(19) United States
(12) Patent Application Publication
(10) Pub. No.: US 2010/0101649 A1
(43) Pub. Date: Apr. 29, 2010

(54) POROUS LAYER, ITS MANUFACTURING PROCESS AND ITS APPLICATIONS

(75) Inventors: Arnaud Huignard, Paris (FR); Nathalie Rohaut, Saint Prix (FR); Sophie Besson, Paris (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: SAINT-GOBAIN GLASS FRANCE, Courbevoie (FR)

(21) Appl. No.: 12/514,361

(22) PCT Filed: Nov. 13, 2007
(86) PCT No.: PCT/FR2007/052336

§ 371 Date: Dec. 10, 2009

(30) Foreign Application Priority Data
Nov. 14, 2006 (FR) 0654886

(51) Int. Cl. H01L 31/00; C03C 17/00; C03C 17/25; B32B 17/00; B32B 3/26; B05D 5/06; H01J 1/00

(52) U.S. Cl. 136/261; 428/314.4; 428/314.2; 427/542; 427/373; 428/312.6; 428/314.8; 428/158; 313/506

(57) ABSTRACT

The present invention relates to a substrate (1) coated with a porous coating (2), to the processes for manufacturing the coating, and to its applications. The porous coating (2) is essentially mineral and of the sol-gel type, having a series of closed pores with at least the smallest characteristic dimension being, on average, equal to or greater than 20 nm but less than or equal to 100 nm.

The present invention relates to the field of porous materials and especially to a porous coating, to its manufacturing process and to its applications.

Essentially mineral porous coatings which are obtained by the sol-gel route are already known. Thus, document EP 1 329 433 discloses a porous coating produced from a sol of tetraethoxysilane (TEOS) hydrolyzed in acid medium with a pore-forming agent based on polyethylene glycol tert-phenyl ether (called “Triton”) with a concentration of between 5 and 50 g/l. Combustion of this pore-forming agent at 500° C. releases the pores. When applied to a glass substrate, this coating forms an antireflection coating used for shop windows or for improving the efficiency of solar cells.

The aim of the present invention is to further extend the range of porous coatings available, especially those that can be produced on an industrial scale, which coatings are applied on substrates in order to give them new, especially optical, electrical, magnetic, physical or chemical, functions or properties, or even preferably to improve the known properties.

The object of the invention is most particularly to provide an easily implementable porous coating having durable properties.

For this purpose, the invention provides a substrate at least partially coated with at least one essentially mineral porous coating of the sol-gel type, the coating having closed pores, a smallest characteristic dimension of which is, on average, at least 20 nm, preferably at least 40 nm, while preferably remaining submicron in size, depending on the envisioned functionalities and/or applications.

Firstly, the Applicant has found that large pores are less sensitive to water and to organic contaminants liable to degrade its properties, especially optical properties (light transmission and reflection, refractive index, etc.). This is all the more important in the case of curtain walling or solar cells, which are constantly exposed to the vagaries of the weather.

Secondly, to obtain pores of well-defined size (characteristic dimensions) and/or shape that are capable of being distributed in space in a desired distribution represents a substantial challenge in particular in the fields of nonlinear optics and optoelectronics. The porous coating according to the invention has a low pore tortuosity.

The regularity of pore formation is important for applications in which it is desired to produce an effect or property which is uniform over the surface of the substrate, in particular when the property is linked to the amount of material and to the size, shape or arrangement of particles, this being especially the case as regards optical properties (antireflection, matched refractive index, etc.).

The porous coating according to the invention may thus have most particularly a substantially uniform distribution throughout its thickness, starting from the interface with the substrate or with an optional sublayer up to the interface with the air or another medium. The uniform distribution may be most particularly useful for establishing isotropic properties of the coating.

The smallest characteristic dimension of the pores (and preferably also the largest dimension) may be even more preferably at least 30 nm but preferably does not exceed 100 nm, or even 80 nm. This depends on the envisioned applications and on the thickness of the coating.

The porosity may furthermore be monodisperse in size, the pore size then being set at a minimum value of 20 nm, preferably 40 nm and even more preferably 50 nm, but preferably not exceeding 100 nm. This depends on the envisioned applications and on the thickness of the coating.

Most (between 80% or more) of the closed pores may preferably have a smallest characteristic dimension, and preferably a largest dimension too, of between 20 and 80 nm.

The proportion of pores by volume may be between 10% and 90%, preferably 80% or less.

The porous coating according to the invention is mechanically stable—it does not collapse even with high poor concentrations. The pores may be easily separated from one another and well individualized. Moreover, the cohesion and mechanical integrity of the porous coating according to the invention are excellent. Most particularly preferred is a porous coating comprising an essentially continuous solid phase, thus forming dense pore walls, rather than a solid phase mainly in the form of (nano)particles or crystallites.

The pores may have an elongate shape, especially like a rice grain. Even more preferably, the pores may have a substantially spherical or oval shape. It is preferred for most of the closed pores, or even at least 80% of them, to have a substantially identical given shape, especially an elongate and substantially spherical or oval shape.

The porous coating according to the invention may advantageously have a thickness of between 10 nm and 10 μm (these limit values being inclusive), in particular between 50 nm and 1 μm and even more particularly between 100 and 200 nm, especially between 100 and 150 nm, as regards the antireflection function in the visible and/or near infrared.

Many chemical elements may form the basis of the porous coating. It may comprise, as essential constituent material, at least one compound from at least one of the elements: Si, Ti, Zr, Al or W, Sb, Hf, Ta, V, Mg, Mn, Co, Ni, Sn, Zn and Ce. It may especially be a simple oxide or a mixed oxide of at least one of the aforementioned elements.

Preferably, the porous coating according to the invention may essentially be based on silica, especially because of its adhesion and its compatibility with a glass substrate.

The pore structure of the coating is dependent on the sol-gel synthesis technique, which makes it possible for the essentially mineral (i.e. mineral or hybrid mineral/organic) material to condense with a suitably chosen pore-forming agent, in particular of well-defined size(s) and/or shape(s) (elongate, spherical, oval, etc.). The pores may be preferably empty, or possibly filled.

Thus, it is possible to choose silica produced from tetraethoxysilane (TEOS), from sodium, lithium or potassium silicate, or from hybrid materials obtained from organosilane precursors of general formula:

R²ₙSi(OR¹)₄₋ₙ

where n is an integer between 0 and 2, R¹ is an alkyl functional group of CₓH₂ₓ₊₁ type and R² is an organic group comprising, for example, an alkyl, epoxy, acrylate, methacrylate, amine, phenyl or vinyl functional group. These hybrid compounds may be used mixed together or by themselves, in solution in water or in a water/alcohol mixture at a suitable pH.

As hybrid coating, it is possible to choose a coating based on methyltriethoxysilane (MTEOS)— an organosilane with a nonreactive organic group. MTEOS is an organosilane possessing three hydrolyzable groups and the organic part of which is a nonreactive methyl.

If it is desired to preserve the organic functional groups, an extracting solvent may be chosen especially for removing the chosen organic pore-forming agent, for example THF in the case of polymethylmethacrylate (PMMA). The porous coating according to the invention may be able to be obtained using at least one solid pore-forming agent. The solid pore-forming agent offers the possibility of varying the pore size of the coating by judicious choice of the size of the pore-forming agent.

The non-localized pore-forming agent of the prior art is of indeterminate shape and expands uncontrollably in the structure. The solid pore-forming agent according to the invention makes it possible to achieve better control of the pore size, especially achieving large sizes, better control of the pore organization, especially a uniform distribution, and better control of the pore content in the coating and better reproducibility.

The solid pore-forming agent according to the invention is also distinguished from other known pore-forming agents, such as micelles of cationic surfactant molecules in solution and, optionally, in hydrolyzed form, or micelles of anionic or non-ionic surfactants, or of amphiphilic molecules, for example block copolymers. Such agents generate pores in the form of narrow channels or more or less round pores of small size between 2 and 5 nm.

However, it may be useful to combine various shapes and/or sizes of pores in a single coating (whether a monolayer or multilayer).

The pore-forming agent according to the invention may be preferably solid, or even hollow, whether a monocomponent or multicomponent, and whether mineral or organic or hybrid.

The agent may preferably be in particulate form, preferably (quasi)spherical form. The particles may preferably be well individualized, thereby enabling the pore size to be easily controlled. It does not matter whether the surface of the pore-forming agent is rough or smooth.

As hollow pore-forming agent, mention may be made in particular of hollow silica beads. As solid pore-forming agent, mention may be made of monocomponent or bicomponent polymeric beads, especially with a core/shell material.

The chosen polymeric pore-forming agent may preferably be removed so as to obtain the porous coating in which the pores may have substantially the shape and size of this pore-forming agent.

The solid, especially polymeric, pore-forming agent may be available in several configurations. It may be stable in solution—typically a colloidal dispersion is used—or it may be in the form of a powder that can be redispersed in an aqueous or alcohol solvent corresponding to the solvent used to form the sol or to a solvent compatible with this solvent.

In particular, a pore-forming agent made of one of the following polymers may be chosen:
polymethyl methacrylate (PMMA);
methyl (meth)acrylate/(meth)acrylic acid copolymers;
polycarbonates, polyesters, polystyrenes, etc. or a combination of several of these materials.

Another type of pore-forming agent used to form the porous coating according to the invention may be in the form of nanodroplets of a first liquid, especially one based on an oil, these being dispersed in a second, especially water-based, liquid, the first liquid and the second liquid being immiscible. For example, this may be a nanoemulsion.

The nanodroplets act as pore-forming agent with a well-defined size. After removal of the nanodroplets, substantially spherical pores with the size of the nanodroplets are obtained.

The second liquid, which may preferably be based on water, may serve for condensing the constituent material of the coating. Preferably, a precursor sol of the constituent material of the coating may be chosen to be compatible with this second liquid and incompatible with the first liquid, so as not to destabilize the nanoemulsion.

The nanodroplets may in particular be oil nanodroplets dispersed in an aqueous medium thanks to a surfactant system that ensures stability. These nanodroplets are generally manufactured by mechanical fragmentation of an oily phase in an aqueous phase in the presence of surfactants. The desired size of the nanodroplets may be obtained in particular by passing them at least once through a high-pressure homogenizer.

In particular, nanoemulsions used in the cosmetics and health fields may be chosen, for example those described in Patent Application WO 02/05683.

The nanodroplets according to the invention may contain at least one oil preferably chosen from animal-based or plant-based oils, mineral oils, synthetic oils, silicone oils, hydrocarbons, especially aliphatic hydrocarbons, and mixtures thereof.

The following oils may in particular be selected:
paraffin oils; and
hydrocarbon vegetable oils.

To further increase the hydrolytic resistance of the porous coating according to the invention, it is also possible to choose to superpose a grafted oleophobic and/or hydrophobic layer, for example one based on the fluorinated organosilane described in the U.S. Pat. No. 5,368,892 and U.S. Pat. No. 5,389,427, as well as based on the hydrolyzable fluorinated alkyl silane(s) described in Patent Application EP 692 463, especially a perfluoroalkylsilane of formula:

CF₃—(CF₂)ₙ—(CH₂)ₘ—SiX₃,

where n is from 0 to 12, m is from 2 to 5 and X is a hydrolyzable functional group, for example a chlorinated or alkoxy group.

Depending of the nature of the surface intended to be coated with the coating it may be recommended, or even necessary, to interpose a primer layer so as to promote adhesion of the coating to its substrate and/or simply to obtain sufficient quality of this adhesion. For this purpose, a layer with an isoelectric potential equal to or greater than the pH of the composition containing the precursor of the constituent material of the porous coating is deposited on the substrate prior to its coming into contact with said composition. In particular, a primer sublayer of the tetrahalosilane or tetraalkoxysilane type, as indicated in Patent Application EP 0484746, may be chosen.

Preferably, the porous coating of the invention is formed with the interposition of a sublayer based on silica or on at least partially oxidized derivatives of silicon chosen from silicon dioxide, substoichiometric silicon oxides and silicon oxycarbide, oxynitride or oxycarbonitride.

The sublayer proves to be useful when the subjacent surface is made of a soda-lime-silica glass since said sublayer acts as a barrier to alkaline metals.

The sublayer proves to be useful when the subjacent surface is made of a plastic, since it enables the adhesion of the porous coating to be enhanced.

This sublayer therefore advantageously comprises Si, O and optionally carbon and nitrogen. However, it may also comprise materials in a minor proportion compared to silicon, for example metals such as Al, Zn or Zr. The sublayer may be deposited by the sol-gel route or by pyrolysis, especially chemical vapor deposition (CVD). The latter technique enables SiOₓC_{y} or SiO₂ layers to be obtained quite easily, especially by direct deposition on the ribbon of float glass in the case of glass substrates. However, it is also possible to carry out the deposition using a vacuum technique, for example by cathode sputtering using an Si target (optionally doped) or a silicon suboxide target (in a reactive atmosphere, for example an oxidizing and/or nitriding atmosphere). This sublayer preferably has a thickness of at least 5 nm, especially a thickness between 10 and 200 nm, for example between 80 and 120 nm.

The constituent material of the coating may be preferably chosen so that it is transparent at certain wavelengths. Furthermore, the coating may have a refractive index at 600 nm and/or at 550 nm at least 0.1 less, and even more preferably 0.2 or 0.3 less, than the refractive index of a coating of the same dense (pore-free) mineral material. Preferably, this refractive index at 600 nm and/or at 550 nm may be equal to or less than 1.3, or equal to or less than 1.1 or indeed close to 1 (for example 1.05).

To give an indication, at 600 nm, a nonporous silica coating typically has a refractive index of around 1.45, a titanium oxide coating has a refractive index of around 2 and a zirconium coating has a refractive index of around 1.7.

The refractive index may be adjusted as required as a function of the pore volume. The following equation may be used as first approximation to calculate the index:

n=fn₁+(1−f)nₚₒᵣₑ,

where f is the volume fraction of the constituent material of the coating, n₁ its refractive index and nₚₒᵣₑ is the index of the pores, generally equal to 1 if they are empty.

By choosing silica, the index may be easily lowered down to 1.05 for any thickness.

The thickness of the coating may also be adjusted by choosing the suitable solvent content.

For an antireflection application, the effect is optimal when the refractive index is equal to the square root of the index of the substrate, i.e. an index of 1.23 per 1.5 index glass, and the product of the index times the thickness is equal to one quarter of the wavelength; also preferably, the index of the porous coating may be less than 1.3 and the thickness may be around 120 nm, for a minimum reflection around 600 nm, or may be around 110 nm to 550 nm.

The refractive index of the porous coating according to the invention is invariant, barely sensitive to the environment.

The constituent material of the coating may preferably be silica, whether hybrid or mineral silica, owing to the low index of this material, as already explained. In this case, the silica may advantageously be doped in order to further improve its hydrolytic resistance in the case of applications in which good resistance is necessary (curtain walling, outdoor applications, etc.). The dopant elements may preferably be chosen from Al, Zr, B, Sn and Zn. The dopant is introduced so as to replace the Si atoms in a molar concentration which may preferably reach 10 mol %, even more preferably up to 5 mol %.

Within the context of the invention, and in the absence of precision, the term “coating” should be understood to mean either a single layer (monolayer) or a superposition of layers (multilayer).

In an advantageous design, the coating may be in the form of a porous multilayer, the porous coatings of the multilayer having pores of different sizes and/or in different amounts. In particular, it may be preferable to manufacture layers in which the porosity increases with the thickness, and therefore going away from the substrate bearing the multilayer, in order to give a multilayer stack with a refractive index in the visible that decreases with increasing thickness, for an even more improved antireflection function. The multilayer may preferably have a thickness of between 100 and 150 nm, preferably around 120 nm, with an average index of 1.2 to 1.25. The sum of the product of the index times the thickness of each of the monolayers may be equal to the product of the index times the thickness of the monolayer equivalent.

In a first example, for a substrate of 1.5 index, the porous layer closest to the substrate may have an index of 1.4 (or it may even be a nonporous silica layer) while that furthest away may have an index of 1.1 or 1.05.

In a second example, a coating is chosen (starting from the substrate) comprising a first layer of index n1 equal to 1.35 and a thickness of 40 nm±10 nm, a second layer of index n2 equal to 1.25 and a thickness of 40 nm±10 nm and a third and final layer of index n3 equal to 1.15 and a thickness of 40 nm±10 nm.

The porous coating may be continuous or discontinuous and occupy substantially the entire main face of the coated substrate.

Moreover, the substrate may preferably be an essentially transparent substrate, especially one based on glass and/or polymer(s) or plastic.

The substrate bearing the porous coating generally has an essentially plane or two-dimensional form with a variable contour, such as for example a plate or disk, but it may also have a volumic or three-dimensional form consisting of the assembly of essentially plane surfaces, for example of cubic or parallelepipedal form, or not.

The substrate may be flat or curved, organic or mineral, especially glass in the form of a sheet, slab, tube, fiber or fabric.

To give examples of glass materials, mention may be made of float glass of conventional soda-lime composition, optionally hardened or toughened by thermal or chemical means, an aluminum borosilicate or sodium borosilicate, or any other composition.

The glass may be colored, bulk-tinted or with a decorative layer.

The glass may be clear or extra-clear and have a very low content of iron oxide(s). For example, it may be one of the glasses sold by Saint Gobain Glass under the “DIAMANT” range.

Advantageously, the main face coated with the porous coating may have a macroscopic relief in the form of hollow or raised features, for example pyramid features, especially with a depth ranging from the order of a fraction of a millimeter to several millimeters, especially ranging from 0.001 mm to 5 mm, for example ranging from 1 to 5 mm.

Preferably, the features are as close as possible to one another and have, for example, their bases less than 1 mm apart, preferably less than 0.5 mm apart and even more preferably contiguous.

The features may, for example, have the form of a cone or a pyramid with a polygonal base, such as a triangular or square or rectangular or hexagonal or orthogonal base, said features possibly being convex, i.e. protruding from the general plane of the textured face, or may be concave, i.e. forming hollows in the mass of the plate.

For the case in which the features have the form of a cone or pyramid, it is preferable for any apex half-angle of said cone or said pyramid to be less than 70° and preferably to be less than 60°, for example ranging from 25° to 50°.

For example, a textured printed flat glass may be chosen such as the glasses sold by Saint Gobain Glass under the “ALBARINO” range.

A transparent substrate with a face thus textured and coated combines the following effects:
light trapping, as demonstrated in Patent Application WO 2003/046617 incorporated by reference, which application discloses, for example, a textured plate having on its surface an array of aligned and completely contiguous concave features, said features having the form of square-based pyramids; and
the antireflection aspect.

To give examples of plastics, mention may be made of polymethyl methacrylate (PMMA), polyvinyl butyral (PVB), polycarbonate (PC) or polyurethane (PU), thermoplastic ethylene/vinyl acetate copolymer (EVA), polyethylene terephthalate (PET), polybutylene terephthalate (PBT), polycarbonate/polyester copolymers, cycloolefin copolymers of the ethylene/norbornene or ethylene/cyclopentadiene type, ionomer resins, for example an ethylene/(meth)acrylic acid copolymer neutralized by a polyamine, thermosetting or thermally crosslinkable polymers, such as a polyurethane, unsaturated polyester (UPE), ethylene/vinyl acetate copolymer, etc., or a combination of several of these materials.

The substrate is preferably formed from a glass material or a plastic of the aforementioned type. It may consist of a single sheet, a laminate formed from several assembled sheets, or else a bulk object, the surface of which, intended to receive the coating, is in general smooth but not necessarily plane. The substrate may be a lamination interlayer.

The substrate may be a glazing pane made of silica-lime-silica glass, especially extra-clear glass, and the coated substrate may have:
a light radiation transmission equal to or greater than 91% or equal to or greater than 92%, or even 93% or 94%, at 600 nm and/or at 550 nm, preferably over the entire range, i.e. typically an increase of at least 2% or even 3% or 4% in the light radiation transmission of the transparent carrier substrate; and/or
a light radiation reflection equal to or less than 7%, or even equal to or less than 4%, at 600 nm and/or at 550 nm or preferably over the entire visible range.

As characteristic wavelength, 600 nm is preferably chosen for photovoltaic applications, whilst 550 nm is chosen instead for shop-window antireflection applications.

The applications, in particular antireflection applications, of the substrate coated with the porous coating are numerous:
as utilitarian glazing pane such as an aquarium, shop-window, greenhouse, counter glass plane, or glazing pane for protecting a painting;
for urban furniture (display panel, bus shelter, etc.) or interior decoration (decorative panel) or for furnishing (furniture wall, etc.);
for an aeronautical, maritime or terrestrial (rail or road) transport vehicle, of the windshield, rear window, sunroof or side window type;
for buildings (windows, French windows); and
for domestic electrical applications (refrigerator door, oven door, furniture showcase, glass-ceramic plate).

In particular in interior applications, mention may also be made of glazing panes intended to protect paintings, for making museum showcases, display cabinets, internal partitions (hospitals, clear rooms, control rooms), television and recording studios, translation booths. In exterior applications, mention may also be made of shop windows, glazed restaurant bays, control towers (for airports and ports), and outdoor separating glazing (for separating spectators in stadiums etc.). Mention may also be made of indicating or advertising panels (for railroad stations, airports, etc.) and cabs for driving industrial machines (cranes, tractors).

In the most conventional antireflection applications, the purpose is to reduce the light reflection of the substrates so as to increase the light transmission thereof. They are therefore optimized only by taking the wavelengths in the visible range into account.

For better efficiency in these conventional antireflection applications, the substrate may preferably have a porous coating on each of its main faces.

This substrate coated with an antireflection coating on each face may have a light transmission equal to or greater than 92% or even equal to or greater than 95% or even 96% to 97% at 550 nm or preferably over the entire visible range, i.e. typically an increase of at least 3% or even 5% or 6% in the light transmission of the transparent carrier substrate.

Moreover, the coated substrate may thus have a transmission over a wavelength range between 400 and 1200 nm of at least 90% for broadband antireflection.

Furthermore, the substrate coated with the porous coating according to the invention may be used as a substrate for an organic light-emitting device (OLED), the coated face being the external face.

This porous coating makes it possible to increase the extraction of the rays already emerging. Extraction at oblique incidence, especially around 30°, may be optimally chosen.

Examples of organic light-emitting stacks are described for example in the document U.S. Pat. No. 6,645,645.

OLEDs are generally divided into two large families depending on the organic material used. If the light-emitting layers are small molecules, the devices are referred to as SM-OLEDs (small-molecule organic light-emitting diodes). If the organic light-emitting layers are polymers, the devices are referred to as PLEDs (polymer light-emitting diodes).

Moreover, for particular applications it may also be necessary to increase the transmission of transparent substrates, and not only in the visible range. This is especially the case for solar panels, in particular thermal solar collectors or photovoltaic cells, for example silicon cells.

Such photovoltaic cells need to absorb the maximum amount of solar energy that they capture, in the visible but also beyond, most particularly in the near infrared, so as to maximize their quantum efficiency that characterizes their energy conversion efficiency.

It is therefore apparent, in order to increase their efficiency, to optimize the transmission of solar energy through this glass in the wavelengths important for photovoltaic cells.

By obtaining a high light transmission in the range covering the wavelengths in the visible and up to those in the near infrared, it is possible to ensure a high energy conversion efficiency, this high transmission resulting within the cell from a variation of a characteristic parameter I_{SC} (short-circuit current) that actually determines this conversion efficiency.

Thus, another subject of the invention is coated substrates according to the invention as outer substrates for at least one photovoltaic cell, the coated face of course being the external face (opposite the cell).

Generally speaking, this type of product is sold in the form of photovoltaic cells connected in series and placed between two substrates, the outer substrate being transparent, especially a glass. It is the combination of substrates and of photovoltaic cell(s) that is termed, and sold under the name of, a “solar module”.

The coated substrate, the external face of which is coated, may therefore be a transparent outer substrate of a solar module comprising one or more photovoltaic cells, especially of the single-crystal or polycrystalline Si type (for example a wafer) or of the a-Si or CIS, CdTe, GaAs or GaInP type.

In one embodiment of the solar module according to the invention, this has an increase in its efficiency, expressed as integrated current density, of at least 2.5% or 2.9% or even up to 3.5% using a coated extra-clear glass compared with a module using an outer substrate made of extra-clear glass not containing an antireflection coating.

In one embodiment of the solar module, this may comprise a first substrate, chosen to be flat and may be in particular of a tinted glass, and a photovoltaic cell, combined with a second flat substrate, especially made of glass, and laminated with the first substrate using a lamination interlayer. Furthermore, a low-index porous coating may be deposited on the lamination face of the first substrate or even deposited on the face of the lamination interlayer of the side facing the first substrate.

The invention may also relate to a multiple glazing unit comprising a first flat substrate, preferably made of glass, especially clear or tinted glass, and a second flat substrate, preferably made of glass, laminated to the first substrate using a lamination interlayer. Furthermore, a low-index porous coating may be deposited on the lamination face of the first substrate or even deposited on that face of the lamination interlayer on the side facing the first substrate.

This multiple glazing unit may be used in all the applications mentioned above (for buildings, automobiles, interior and external applications, etc.).

This porous coating acts as an optical separator between the outer glass and the photovoltaic cell, or between the first and second substrates. In this way it is possible to maintain the desired appearance, for example a colored or tinted appearance, this being particularly useful for architectural curtain walling. The effect is optimal if the lowest possible refractive index is chosen.

Also in the latter lamination applications, the low-index porous coating, preferably as already described above (large pores, produced by beads or nanodroplets, etc.), may have an optical index n₂ lower than the optical index n₁ of the first substrate, especially so that n₂−n₁ is equal to or greater than 0.1, or even 0.2, and for example up to 0.4, preferably over the entire visible range.

In particular for a first glass substrate of index 1.5, an index n₂ of 1.4 or even down to 1.1 may be chosen.

The thickness of the porous coating forming an optical separator may preferably be equal to or greater than 200 nm, or even 400 nm, but preferably less than 1 μm.

In a third laminated configuration, a luminous laminated structure is proposed that comprises:
a transparent first flat substrate, of given optical index n₁, especially made of a clear or extra-clear glass or even plastic;
a bulk-tinted second flat substrate, especially a tinted glass;
a lamination interlayer between the first and second substrates;
a porous coating forming an optical separator, deposited on the lamination interlayer or on the first substrate, the porous coating being of optical index n₂, the difference n₂−n₁ being equal to or greater than 0.1 or even 0.2, and for example up to 0.4, preferably over the entire visible range;
a light source coupled into the edge of the first substrate, especially light-emitting diodes (LEDs); and
an internal backscattering network between the porous coating and the first substrate and/or an external scattering network on the external face of the first substrate.

The porous coating forming an optical separator reflects the light rays into the first transparent substrate forming an optical waveguide.

The thickness of the porous coating may preferably be equal to or greater than 200 nm or even 400 nm, but preferably less than 1 μm.

For example, in particular for a first glass substrate of 1.5 index, the porous coating may be chosen to have an index of 1.4 to 1.1.

In the case of an internal backscattering network, this porous coating may be deposited only between the internal network or else also cover the internal network.

The internal network is backscattering, preferably has a diffuse reflection factor equal to or greater than 50%, or even 80%.

The external network is scattering, serves for extracting light, and preferably has a diffuse transmission factor equal to or greater than 50% or even 80%.

The scattering or backscattering network may be formed from scattering features, for example with a width (on average) ranging from 0.2 mm to 2 mm, preferably less than 1 mm, and of micron-size thickness, for example a thickness of 5 to 10 μm. The spacing (on average) between the features may be between 0.2 and 5 mm. To form a network, a coating may be textured.

The scattering or backscattering network may preferably be essentially mineral, based on a mineral binder and/or mineral scattering particles.

To give an example of a backscattering network, it is possible to choose a scattering layer as described in the published French Patent Application FR 2 809 496.

The second tinted substrate may for example preserve heat coming from the sun. A certain transparency may be maintained for viewing the outside, for example for the roofs of maritime transport or terrestrial transport vehicles (automobiles, industrial vehicles, etc.).

Glasses VG10 or VG40, of the VENUS range, sold by Saint-Gobain Glass, may for example be chosen.

The glass VENUS VG10 has the following characteristics: T_{L} between 10 and 15% and T_{E} between 8 and 12.5% (according to the TE-PM2 standard) depending on the thickness. The glass VENUS VG40 has the following characteristics: T_{L} between 35 and 42% and T_{E} between 22 and 28% (according to the TE-PM2 standard) depending on the thickness.

For architectural applications, it is possible to use for example bronze, gray or green bulk-tinted glasses of the PARSOL range sold by Saint-Gobain Glass. For example, the glass PARSOL GRIS has the following characteristics: T_{L} between 26 and 55% (under illuminant D₆₅) and T_{E} between 29 and 57% (according to the PM2 standard) depending on the thickness.

The illumination may be decorative, ambient, colored or not. The illumination may be homogeneous or not, depending on the intended application (logoed glazing, tinted glazing, decorative glazing, etc.).

In the luminous laminated structure, the coated interlayer, or preferably the coated first substrate, may be the substrate coated with the porous coating already described above.

The illuminating laminated structure may most particularly be a luminous roof, a vehicle door, a luminous double-glazing unit for buildings, exterior or interior applications, such as curtain walling, partitions, doors, windows, tables or shelves.

In these examples of laminated structures, the porous coating forming an optical separator may alternatively be formed using various techniques of the prior art.

In a first embodiment, the pores are the interstices of a non-compact stack of nanoscale beads, for example silica beads, this coating being described for example in the document US 2004/0258929.

In a second embodiment, the porous coating is obtained by depositing a condensed silica sol (silica oligomers) densified by NH₃ vapor, this coating being described for example in the document WO 2005/049757.

In a third embodiment, the porous coating may also be of the sol-gel type, as described in the document EP 1 329 433. The porous coating may also be obtained using other known pore-forming agents: micelles of cationic surfactant molecules in solution, and possibly in hydrolyzed form, or micelles of anionic or non-ionic surfactants, or amphiphilic molecules, for example block copolymers.

As lamination interlayer, it is possible in particular to choose a sheet of a thermoplastic, for example a sheet of polyurethane (PU), polyvinyl butyral (PVB) or ethylene-vinyl acetate (EVA), or of a multicomponent or single-component resin which is thermally crosslinkable (epoxy or PU) or ultraviolet-crosslinkable (epoxy, acrylic resin).

Moreover, when the substrate bearing the porous coating according to the invention is a glazing pane, when coated, this may be heat-treated at a temperature of 350° C. or higher, preferably 500° C. or even 600° C. or higher, for a toughening (or bending) operation. Preferably the glazing pane is a toughened glass.

This is because the porous coating according to the invention has the capability of withstanding high-temperature heat treatments without cracking and without appreciable deterioration in its optical, durability and hydrolytic resistance properties. It thus becomes advantageous to be able to deposit the porous coating before the glass is heat-treated, especially before toughening and bending/forming it, typically between 500° C. and 700° C., without posing any problem, since it is simpler from the industrial standpoint to carry out the deposition before any heat treatment. Thus, it is possible to have a single antireflection configuration, whether or not the carrier glass is intended to undergo a heat treatment.

It is unnecessary to carry out beforehand a heat treatment at a lower temperature, typically between 350° C. and 450° C., in order to densify the coating and possibly eliminate the pore-forming agent. The densification/formation of the porous coating may thus be carried out during the toughening or bending operation.

Moreover, another subject of the invention is a process for manufacturing a substrate with a porous coating, the process being of the sol-gel type comprising the following successive steps:
maturing of a sol, this being a precursor of the constituent material of the coating, of doped or undoped silica oxide type, especially a hydrolyzable compound such as a halide or a silicon alkoxide, in a solvent, especially an aqueous and/or alcoholic solvent;
mixing with a solid polymeric pore-forming agent in the form of particles and/or a liquid pore-forming agent in the form of nanodroplets in a first liquid, especially an oil, these being dispersed in an immiscible, especially water-based, second liquid, the particles or the nanodroplets preferably being at least 20 nm, especially between 40 and 100 nm, in size (smaller and/or larger characteristic dimension);
deposition on the substrate;
condensation of the precursor around the pore-forming agent; and
heat treatment, especially a toughening and/or bending/forming operation, at least 500° C., even at least 600° C., for a time not exceeding 15 minutes, preferably not exceeding 5 minutes.

The solid pore-forming agent may advantageously comprise beads, preferably polymeric beads, especially of the PMMA, methylmethacrylate/acrylic acid copolymer or polystyrene type.

The liquid pore-forming agent in the form of nanodroplets may advantageously comprise the abovementioned oils.

The heat treatment may thus incorporate the step of removing the pore-forming agent and of completing the condensation, in order to densify the coating.

The deposition on the substrate may be carried out by spraying, or by immersion in and withdrawal from the silica sol (dip coating), by spin coating, by flow coating or roll coating.

The process may furthermore include solvent removal at a temperature equal to or below 120° C. or 100° C.

As a first variant, useful in particular in the case of a plastic or glass substrate (in particular one already toughened) and/or with a hybrid sol, said chosen polymeric pore-forming agent may be removed by addition of a polymer-extracting solvent, for example THF in the case of PMMA, and the densification may be carried out by a UV treatment, for example for a hybrid silica sol with UV-crosslinkable (methacrylate, vinyl, acrylate, etc.) functional groups.

As a second variant, useful in the case of a plastic and/or glass substrate (in particular already toughened), the precursor sol of the constituent material of the coating is a lithium, sodium or potassium silicate, for example deposited by flow coating. In the case of a plastic (or glass) substrate, said chosen polymeric pore-forming agent is removed by the addition of a polymer-extracting solvent, for example THF in the case of PMMA, and the densification takes place by infrared drying, possibly with blown air, at a temperature of 100° C. or below, for example 80° C.

In the case of a glass substrate, the removal of said chosen polymeric pore-forming agent and the densification may be carried out at 350° C. and upward.

The details and advantageous characteristics of the invention will now become apparent from the following nonlimiting examples using the figures:

FIGS. 1 to 4b are scanning electron microscopy images in cross section and top view of porous coatings according to the invention;

FIGS. 5 to 7 illustrate graphs showing the transmission spectra of various bare substrates or substrates coated with the porous coating according to the various examples of the invention or according to comparative examples;

FIGS. 8 to 10 illustrates three solar modules incorporating a substrate coated with a porous coating according to the invention;

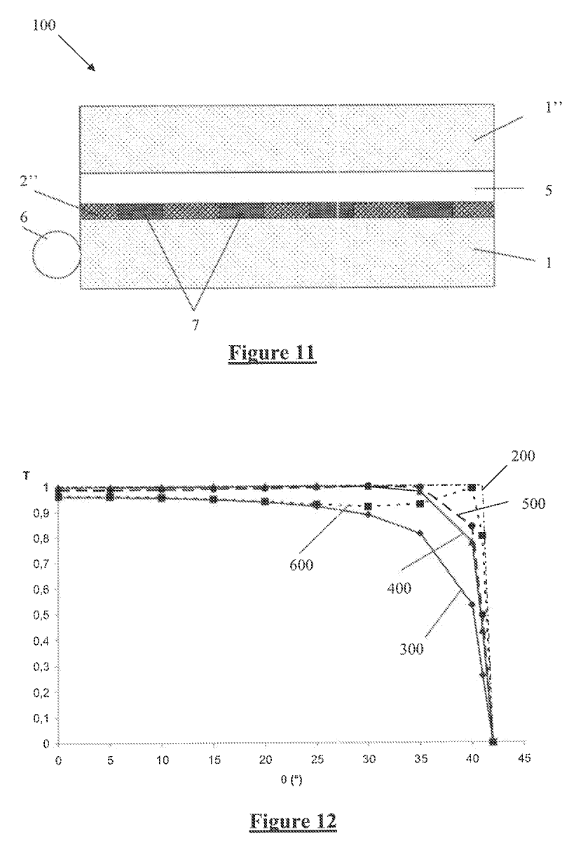

FIG. 11 illustrates a tinted luminous laminated glazing pane incorporating a substrate coated with a porous coating according to the invention; and

FIG. 12 illustrates the transmission factor as a function of the angle of an organic light-emitting device, the substrate of which is bare or coated on its external face with a porous coating according to the invention.

### MANUFACTURING EXAMPLES

### Series 1

Specimens measuring 10 cm×10 cm of a float glass, an extra-clear soda-lime-silica glass of 2.1 mm in thickness were cut, such as the glass Diamant sold by Saint-Gobain Glass. These specimens were washed with an RBS solution, then rinsed, dried and subjected to a UV ozone treatment for 45 minutes.

Each of these specimens was intended to receive a porous coating according to the invention on the tin or bath face. The float glass may be provided with an alkali-metal barrier sublayer, for example of the SiO₂, SiOC or SiNₓ type, with thicknesses of around 50 to 100 nm, optionally by adjusting the chosen thicknesses and indices.

The process for forming the porous coating is described below.

The first step of this process consisted in preparing the liquid treatment composition, called hereafter the “sol”.

The sol was obtained by mixing 20.8 g of tetraethylorthosilicate, 18.4 g of absolute ethanol and 7.2 g of an aqueous solution of pH=2.5 acidified using HCl. The corresponding molar ratio was 1:4:4. This composition was preferably mixed for four hours so as to obtain complete hydrolysis of the alkoxide precursor.

The second step of this process consisted in mixing the silica sol obtained above with the pore-forming agent, namely submicron polymeric beads, in various proportions and of various types depending on the specimen.

In a first configuration (trials 1 to 4), PMMA beads dispersed in ethanol were incorporated (20 wt %). Various amounts of beads were added so as to obtain a wide refractive index range. A given ethanol content is preferential according to the desired coating thickness. These beads had a total average diameter of nm±10 nm measured by dynamic light scattering using a Malvern Nano ZS instrument.

In a second configuration (trials 5 to 6), the silica sol was incorporated into a polymeric dispersion comprising methyl methacrylate/acrylic acid copolymer beads dispersed in water (16 wt %, at pH=4). These beads had a total average diameter of 75 nm±30 nm measured by dynamic light scattering using a Malvern Nano SZ instrument.

The third step was the deposition of the mixture, preferably prefiltered with a 0.45 μm filter. The deposition was carried out by spin coating on a first face of the glass, the side facing the tin or bath. The rotation speed was for example 1000 revolutions per minute.

Other equivalent deposition techniques are dip coating, spray coating, laminar coating, roll coating and flow coating.

The fourth step corresponded to a heat treatment.

Thus, a first portion of specimens 1 to 6 was heated at 450° C. for 3 hours so as to remove the beads, to densify the coating and to remove the solvent(s). Preferably, after deposition of the sol, a prior solvent removal step, for example at 100° C. for 1 hour, could be optionally carried out in order to reduce the risk of cracks appearing due to excessively fierce heating.

A second portion of specimens 1 to 6 was subjected to a toughening treatment a 640° C. for 10 minutes, making it possible to remove the beads, to densify the coating and to obtain a toughened glass. Preferably, after deposition of the sol, a prior solvent removal step, for example at 100° C. for 1 hour, could be optionally carried out in order to reduce the risk of cracks appearing due to excessively fierce heating.

An optional fifth step consisted in adding an overlayer. Thus, a portion of specimens 1 to 6 was functionalized with the perfluorosilane CF₃(CF₂)₇CH₂CH₂Si(OH)₃ according to the Aquacontrol® procedure described in Patent Application EP 799 873, in order to further increase the hydrolytic resistance, in particular with a view to applications outdoors or in a wet atmosphere.

In the case of a plastic substrate, only the fourth step was modified: the beads were removed using a specific solvent, it remaining necessary to carry out a heat treatment at 80° C. in order to densify the coating, and/or a UV treatment.

FIGS. 1 and 2 show scanning electron microscopy images in plane cross section of specimens 2 and 3.

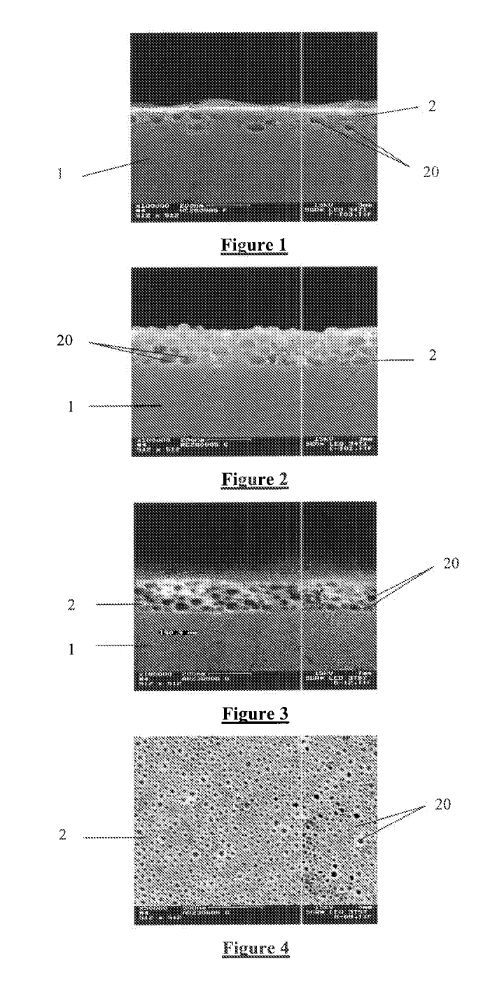

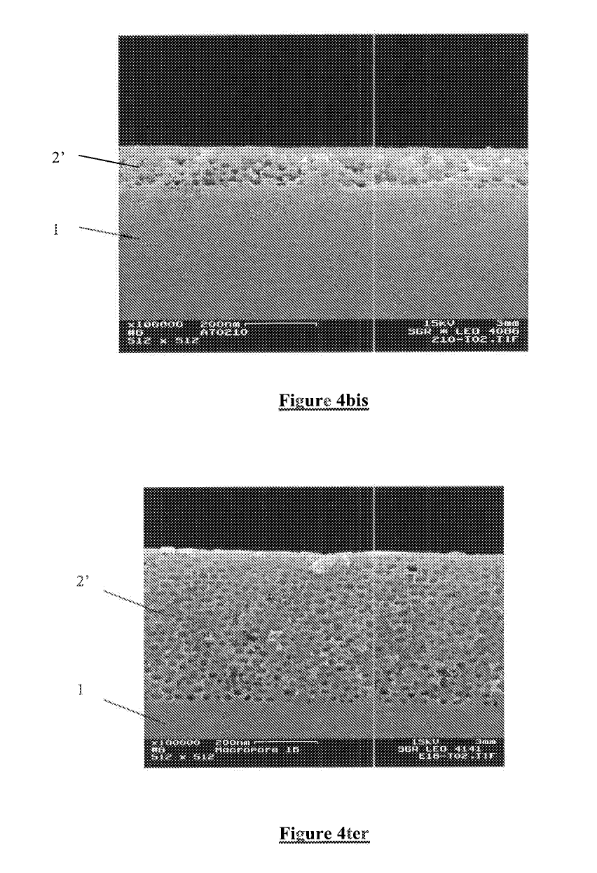

FIGS. 3 and 4 respectively show scanning electron microscopy images in plane cross section and in bottom view of specimen 5.

For all the specimens, it was found that the porous coating 2 had well individualized and uniformly distributed pores 20 throughout its thickness, from the interface with the glass substrate 1 up to the interface with the air.

The surface of the porous coating 2 was remarkably smooth owing to the removal of the polymeric beads without crack formation. The haze was less than 0.5%.

Using PMMA beads, the pores of the porous coating had a size of between 50 and 70 nm, this being close to the size of said beads.

Using methyl methacrylate/acrylic acid copolymer beads, the pores of the porous coating had a size of between 30 and 70 nm, substantially reproducing the spread in size of said beads.

Table 1 below gives the various characteristics of the coatings of trials 1 to 6.

TABLE 1

| | | Volume | | | |
|---|---|---|---|---|---|
| | Sol | of bead | | | |
| | volume | solution | % volume | Solvent | Thickness |
| Trial | (μl) | (μl) | of beads | (μl) | (nm) |
| 1 | 200 | 260 | 55.6 | 2500 | 100 |
| 2 | 400 | 160 | 33.3 | 2500 | 130 |
| 3 | 200 | 360 | 68.9 | 2500 | 150 |
| 4 | 1000 | 600 | 55.6 | 400 | 800 |
| 5 | 600 | 260 | 62.2 | 2500 | 150 |
| 6 | 600 | 75 | 42.2 | 2500 | 120 |

The thicknesses of the coatings were measured using SEM micrographs.

Another precursor, especially a sodium, lithium or potassium silicate, in an amount of 5 to 30% in solution in water, could be chosen.

Thus, as a variant, in the case of a plastic or glass substrate, a potassium, sodium or lithium silicate was chosen as binder, the beads were removed, either by a specific polymer-extracting solvent, for example THF in the case of PMMA, followed by drying at 80° C., for example by infrared heating with blown air, or by a heat treatment at 350° C. or higher for a time of at least one hour in order to remove the beads.

### Series 2

Specimens of Diamant glass were prepared as in series 1.

A silica sol was produced by hydrolysis of tetraethylorthosilicate (TEOS) in water acidified with hydrochloric acid to pH=2.5. The mass concentration of TEOS in the formulation was 40%. The sol was hydrolyzed with vigorous stirring for 90 minutes (the initially cloudy solution became clear).

The solid pore-forming agent used was one of the acrylic beads in suspension in water (40% solids content; pH=5). These beads have a total average diameter of 70 nm±20 nm measured by dynamic light scattering using a Malvern Nano ZS instrument.

After incorporation of the pore-forming agent, the formulation was diluted with water acidified using hydrochloric acid (pH=2.5) in order to adjust the thickness.

In another embodiment, an alumina precursor was added to the formulation for the purpose of doping the silica. This precursor was aluminum acetylacetonate or AL (acac). It was introduced in an amount of 5 mol % as a replacement of the silicon. In practice, Al (acac) was dissolved in the dilution water before being added to the sol. The pore-forming agent was added to the formulation last.

The various formulations were deposited by spin coating at 2000 rpm. The specimens were then heat-treated directly for 3 minutes at 700° C.

The details of the various trials are given in Table 2.

TABLE 2

| | | Volume of | | | |
|---|---|---|---|---|---|
| | Sol | bead | | Al(acac) | |
| | volume | solution | % volume | mass | Solvent |
| Trial | (μl) | (μl) | of beads | (mg) | (μl) |
| 7 | 3230 | 570 | 55% | 0 | 6200 |
| 8 | 3090 | 570 | 55% | 31 | 6340 |

The coatings had a thickness of about 110 nm, and pores of about 70 nm (SEM observations).

### Series 3

In this third series, only the pore-forming agent was different from that of series 2. In this case it was a nanoemulsion of paraffin oil (16.5 wt %) in water. The size of the oil droplets was 32 nm±10 nm measured by dynamic light scattering using a Malvern Nano ZS instrument.

A silica sol formulated in water was used to prevent the emulsion from destabilizing.

As in Examples 6 and 7, it was possible to dope the silica with alumina.

The coatings were deposited and then heat-treated under the same conditions as in series 2.

The details of the various trials are given in table 3.

TABLE 3

| | | Volume of | | | |
|---|---|---|---|---|---|
| | Sol | nanodroplet | | Mass of | |
| | volume | solution | % volume of | Al(acac) | Solvent |
| Trial | (μl) | (μl) | nanodroplets | (mg) | (μl) |
| 9 | 3230 | 1380 | 55% | 0 | 5390 |
| 10 | 3090 | 1380 | 55% | 31 | 5530 |

The coatings had a thickness of about 110 nm and 30 nm pores (SEM observations).

FIGS. 4a and 4b show respectively scanning electron microscopy images in plane cross section of the series 3 type.

FIG. 4a shows a thin porous coating 2′ on a glass 1 and FIG. 4b shows a thick porous coating 2′ on a glass 1.

Optical Properties

Table 4 below shows the refractive index in the visible of coatings 1 to 10.

TABLE 4

| | Thickness | |
|---|---|---|
| Trial | (nm) | n |
| 1 | 100 | 1.2 |
| 2 | 130 | 1.3 |
| 3 | 150 | 1.14 |
| 4 | 800 | 1.2 |
| 5 | 150 | 1.17 |
| 6 | 120 | 1.26 |
| 7 | 110 | 1.25 |
| 8 | 120 | 1.27 |
| 9 | 100 | 1.27 |
| 10 | 110 | 1.30 |

FIG. 5 shows the transmission T profiles between 400 and 1200 nm for a bare extra-clear glass of the Diamant type (curve A) and for specimens of trial 1:
a first specimen, heat-treated at 450° C. without fluorosilane grafting (curve B);
a second specimen, heat-treated at 640° C. and fluorosilane-grafted (curve C);
a third specimen, heat-treated at 640° C. without fluorosilane grafting (curve D); and
a fourth specimen, not heat-treated at 640° C. and fluorosilane-grafted (curve E).

This figure shows an increase of 3 or 4% in the light transmission in the visible and 2% in the near infrared for the specimens of trial 1 compared with the comparative bare glass. Neither the grafting nor the treatment at 640° C. affects the optical properties.

Throughout the entire 400-1200 nm range, the transmission T is greater than 90%, especially equal to or greater than 93% between 400 and 700 nm.

Moreover, the reflection R is approximately constant, around 5 to 5.5% between 400 and 700 nm and around 8% between 700 and 1200 nm.

Similar results were obtained with the specimens of trials 2 to 10.

At a variant, coatings according to the processes described above in the case of series 1 to 3 were deposited with the DIAMANT extra-clear glass being replaced with a clear glass of the PLANILUX type with a thickness of 2.1 mm.

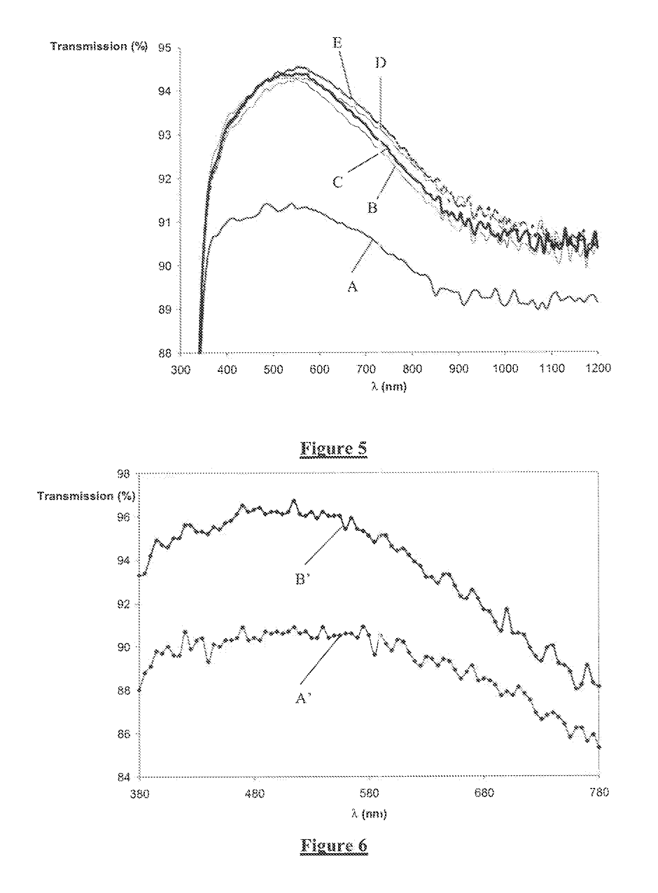

FIG. 6 thus shows the transmission T profiles between 300 and 1200 nm for a bare Planilux glass (curve A′) and for a second specimen with a porous coating on each face (curve B′), each coating being treated at 450° C.

The latter specimen was for a conventional antireflection application: shop windows, glazing panes for protecting paintings, shop counters.

FIG. 6 shows a 5 to 6% increase in the transmission T in the visible for the “two-coating” specimen, with a transmission of 96% at 550 nm. Moreover, the reflection R is approximately constant, around 2-2.5% between 400 and 700 nm, especially 1.9 at 550 nm, compared with about 5% with a single coating.

Tests

Specimens 1 to 6 were subjected to various tests (explained in detail below).

A first test, for determining the durability, is often referred to as a “climate test” according to the IEC 61250 standard. The coatings underwent 20 thermal cycles from −40° C. to +80° C.

As second test, these coatings underwent a damp heat resistance test, consisting in leaving the coatings for 1000 hours at 85° C. in a chamber in which the atmosphere had a controlled relative humidity of 85% (IEC 61215 standard).

As third test, these coatings were subjected to the chemical resistance test known as the neutral salt fog or NSF test according to the DIN 50021 standard. The protocol was the following: the coatings were subjected to an aqueous fog containing 50 g/l of NaCl with a pH of 7 at a temperature of 35° C. for 500 hours.

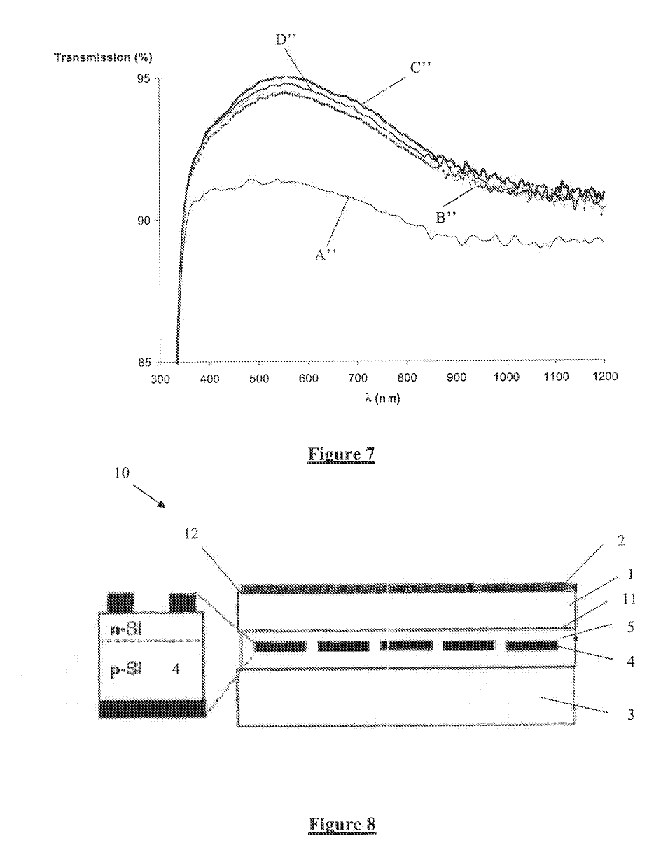

FIG. 7 thus shows the light transmission profiles between 300 and 1200 nm for a bare DIAMANT glass (curve A″) and for the following specimens of series 1:
specimen heat-treated at 640° C. with and without grafting, not having undergone any test (curve B″);
specimen heat-treated at 640° C. with and without grafting, and having undergone the first test (curve C″);
specimen heat-treated at 640° C. with and without grafting, and having undergone the second test (curve D″);
specimen heat-treated at 640° C., and having undergone the third test (curve E″).

This figure shows that the light transmission is unchanged, just like the light reflection and the refractive index.

Specimens 7 to 10 underwent the following tests:
the damp heat test defined above; and
an abrasion resistance (Opel) test according to the DIN 61200 standard.

Table 5 gives the energy gain values provided by the antireflection coating for a silicon-based photovoltaic module before and after these two tests.

The energy gain is defined as follows:

$$G = \frac{{I}_{AR} - {I}_{0}}{{I}_{0}}$$

where I_{AR} and I₀ are the current densities obtained with and without the antireflection coating respectively.

The current density is defined as follows:

$$I = {\int }_{300}^{1300} D ( λ ) T ( λ ) {R}_{cell} ( λ )$$

where:

D(λ) is the solar emission spectrum;

T(λ) is the spectral transmission of the glass; and

R_{cell}(λ) is the quantum efficiency of the photovoltaic cell at a wavelength λ. Here we considered a silicon cell.

TABLE 5

| | | Gain after | Gain after |
|---|---|---|---|
| | Gain at | 1000 h of the | 5000 Opel |
| Trial | t = 0 | damp heat test | cycles |
| 7 | 2.9% | 1.7% | 2.2% |
| 8 | 2.9% | 2.9% | 0.7% |
| 9 | 3.2% | 1.5% | 2.8% |
| 10 | 3.2% | 2.7% | 1.9% |

These tests show the positive effect of the alumina doping with regard to the hydrolytic resistance. This doping results in a drop in the mechanical resistance, but this is lower in the case of the pore-forming agent of the oil nanoemulsion type.

The processes described above may also be modified as follows.

Other known pore-forming agents could also be incorporated with the beads, for example micelles of cationic surfactant molecules in solution and, optionally, in hydrolyzed form or micelles of anionic or non-ionic surfactants, or amphiphilic molecules, for example block copolymers. Such agents generate pores in the form of narrow channels of more or less round pores of small size between 2 and 5 nm. The cationic surfactant may be cetyltrimethylammonium bromide, the precursor of the material is in solution in its form resulting from a hydrolysis in acid medium: Si(OH)₄, and the surfactant Si:molar ratio is between 10⁻⁴ and 0.5.

As a variant, the porous coating may be chosen to coat a face textured with a macroscopic relief, especially printed laminated extra-clear glass such as the glass ALBARINO from Saint-Gobain Glass or else a clear glass of the PLANILUX type from Saint-Gobain Glass.

As another variant, a stack of porous coatings may also be provided, preferably with porosity increasing with increasing thickness.

Solar Module

Specimens 1, 6 and 10 were preferably chosen as outer glass pane of a solar module.

The module 10 shown in FIG. 8 was made up as follows: the glass pane 1 provided with the antireflection porous coating 2 on its outer face 12 (on the side facing the air) was joined via its inner face 11 to a glass pane 3 called the “inner” pane. This inner glass pane 3 was made of clear or extra-clear toughened glass 2.1 mm in thickness.

More precisely, the photovoltaic cells 4 were placed between two glass panes 1, 3 and then poured into the space between the panes was a polyurethane-based curable polymer 5 in accordance with the teaching of Patent EP 0 739 042.

Each photovoltaic cell 4 was made up, in a known manner, from silicon wafers forming a p/n junction and front and rear printed electrical contacts. The silicon photovoltaic cells could be replaced with solar cells using other semiconductors (such as CIS, CdTe, a-Si, GaAs, GaInP).

For comparison, a solar module identical to the previous one, but with an outer glass pane made of extra-clear glass not including the antireflection porous coating according to the invention, was mounted.

The increase in efficiency, expressed as integrated current density, was about 2.9% compared with the conventional module.

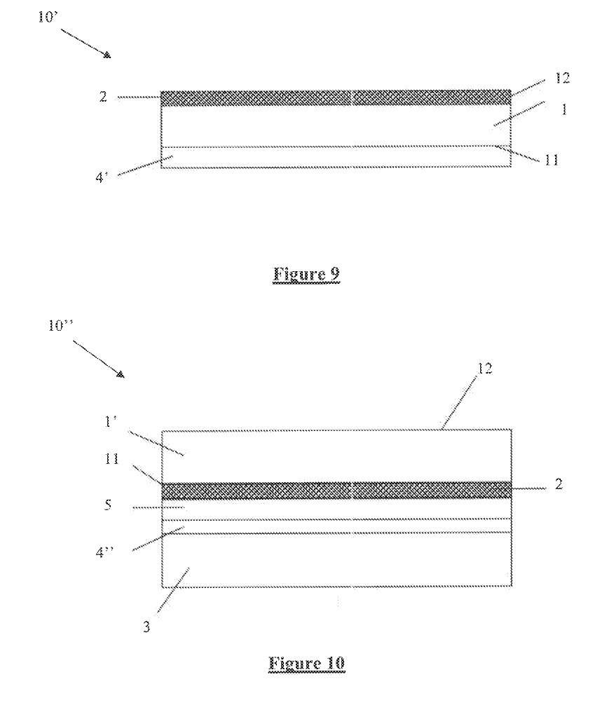

In a first variant shown in FIG. 9, the module 10′ comprised the glass pane 1 with the porous coating 2 on its outer face 12 and one or more thin-film photovoltaic cells 4′, for example of the a-Si, CdTe, GaAs or GaInP type, on its inner face.

More precisely, and conventionally, each photovoltaic cell comprised the following stack:
a transparent electroconductive (TCO) layer;
the a-Si-type active layer (monolayer or multilayer); and
a metallic reflector, for example made of silver or aluminum.

In a second variant shown in FIG. 10, the photovoltaic cells 4″ were of the CIS type on the glass pane 3.

The photovoltaic cells 4″ were laminated with a lamination interlayer 5, for example made of EVA, to the first glass pane 1′. Like the first glass pane 1, a tinted glass pane 1′ was preferably chosen with, on its internal lamination face 11, the low-index porous coating 2 of preferably specimens 3, 4 or 5, with the lowest possible index and a thickness of at least 150 nm.

This type of module, for example on curtain walling, retains the color of the tinted glass.

Optionally, an external antireflection coating, especially such as the porous coating of the specimens 1 and 6 to 10, could be added.

As a variant, a laminated single glazing panel may be formed, the porous coating forming an optical separator.

Luminous Laminated Structure

A luminous automobile roof 100 was produced comprising:
a flat transparent first substrate 1, of optical index n₁ equal to about 1.5, for example a clear or extra-clear glass;
a flat bulk-tinted second substrate 1″, especially a tinted glass such as the glass VG10;
a lamination interlayer 5, for example a PVB interlayer, between the first and second substrates;
a discontinuous porous coating 2″ forming an optical separator deposited on the first glass pane, the coating 2″ having an optical index n₂ of for example 1.1 and a thickness of 400 nm;
an illumination source for illumination via the edge of the first substrate, in the form of light-emitting diodes 6 preferably housed in a groove of the first glass pane 1; and
an internal backscattering network 7 between the porous coating and the first substrate, in the form of features of suitable dimensions, depending on the desired illumination.

As regards the porous coating, one of the coatings of the aforementioned examples may be chosen, where necessary adjusting the thickness.

OLED Device

FIG. 12 illustrates the transmission factor as a function of the angle of an organic light-emitting device incorporating a bare substrate or a substrate coated on its external face with a porous coating obtained with a pore-forming agent of the nanoparticle or nanodroplet type in accordance with the invention, for example using the manufacturing processes already described in the case of examples 1 to 10.

The profile of curve 200 corresponds to the ideal case in which all of the light rays, irrespective of their angle of incidence at the glass/air interface, are extracted from the glass.

Curve 300 corresponds to a bare glass pane.

Curve 400 corresponds to a glass pane coated with the porous coating for extraction optimization at 0°.

Curve 500 corresponds to a glass pane coated with the porous coating for extraction optimization at 32°.

Curve 600 corresponds to a glass pane coated with the porous coating for extraction optimization at 40°.

Moreover, the normalized form ratio A defined by the following equation:

$$A = \frac{\int T ( θ ) d θ}{\int R ( θ ) d θ} ,$$

in which:

Tθ corresponds to the light transmission as a function of the angle of incidence θ of the light beam; and

Rθ is a rectangular profile as a function of the angle of incidence θ of the light beam, between 0° and the limiting angle of refraction between glass and air, the magnitude of R(x) being normalized to 1, the form ratio A therefore defining the departure from ideality of the configuration, is given in Table 6. For each extraction optimization at a given angle, a preferred optical index and thickness are obtained.

TABLE 6

| Optimization angle | n | e(nm) | Form ratio A |
|---|---|---|---|
| Bare glass (comparative) | | | 0.875 |
| 0° (coated glass) | 1.22 | 135 | 0.965 |
| 32° (coated glass) | 1.19 | 160 | 0.968 |
| 40° (coated glass) | 1.1 | 280 | 0.941 |

An appreciable increase in the form ratio is observed with the porous coating.

1. A substrate at least partially coated with at least one essentially mineral porous coating of the sol-gel type having a series of closed pores, at least the smallest characteristic dimension of which is, on average, at least 20 nm but does not exceed 100 nm.

2. The coated substrate as claimed in claim 1, wherein the pores have a substantially spherical or oval shape.

3. The coated substrate as claimed in claim 1, wherein the porous coating is essentially based on hybrid or mineral silica, doped with at least one dopant selected from the group consisting of Al, Zr, B, Sn, and Zn.

4. The coated substrate as claimed in claim 1, wherein the porous coating is obtained with at least one essentially solid pore-forming agent in particulate form, the pore-forming agent being optionally removed.

5. The coated substrate as claimed in claim 1, wherein the porous coating is obtained with at least one pore-forming agent in the form of nanodroplets of a first oil-based liquid, said nanodroplets being dispersed in a second water-based liquid, the first and second liquids being immiscible.

6. The coated substrate as claimed in claim 1, wherein the porous coating is coated with a grafted hydrophobic and/or oleophobic layer, based on a fluorinated organosilane or based on a perfluoroalkylsilane.

7. The coated substrate as claimed in claim 1, wherein the porous coating is placed on a sublayer capable of being an alkali metal barrier and/or an adhesion promoter, said sublayer being based on silica or on an at least partially oxidized derivative of silicon chosen from silicon dioxide, substoichiometric silicon oxides and silicon oxycarbide, oxynitride or oxycarbonitride.

8. The coated substrate as claimed in claim 1, wherein the porous coating has a refractive index at 600 nm or at 550 nm at least 0.1 less than the refractive index of a mineral coating of dense identical mineral material, and which does not exceed 1.3.

9. The coated substrate as claimed in claim 1, wherein the porous coating is in the form of a porous multilayer, the porous coatings of the multilayer having pores of different sizes and in different proportions.

10. The coated substrate as claimed in claim 1, wherein the thickness of the porous coating is between 100 and 200 nm.

11. The coated substrate as claimed claim 1, wherein the substrate is transparent, and based on glass and/or one or more polymers, and the optical index of the porous coating is less than the optical index of the substrate.

12. The coated substrate as claimed in claim 1, wherein the substrate is flat and made of glass, and the coated face has a macroscopic relief having features with a depth of the order of a fraction of a millimeter to several millimeters.

13. The coated substrate as claimed claim 1, wherein the substrate is a glazing pane made of soda-lime-silica glass, and the coated substrate has a radiation transmission equal to or greater than 91% at 600 nm and/or at 550 nm and equal to or greater than 90% between 400 and 1200 nm and/or a light radiation reflection equal to or less than 7% at 600 nm and/or at 550 nm.

14. The coated substrate as claimed in claim 1, wherein the substrate is a glazing pane and the coated glazing pane is heat-treated at a temperature of 450° C. or higher, and is a toughened glass.

15. An aquarium, shop-window, greenhouse, counter or store glass pane, a display cabinet, a glazing pane for protecting a painting, a window pane for aeronautical, maritime or terrestrial transport vehicles, of the windshield, rear window, sunroof or side window type, or a glazing pane for buildings, of the window, French window, glazed bay or control tower type, or a separating window, or for urban furniture of the display panel or bus shelter type, or for interior decoration, of the decorative panel or internal partition type, for domestic electrical applications, a refrigerator or oven door, showcase, furniture front or glass-ceramic plate comprising the coated substrate as claimed in claim 1, it being understood that the substrate has said porous coating on both of its main faces.

16. A transparent substrate of an organic light-emitting device comprising the coated substrate as claimed in claim 1, the coated face being the external face.

17. A transparent outer substrate of a solar module comprising at least one photovoltaic cell of the Si, CIS, CdTe, a-Si, GaAs or GaInP type comprising the coated substrate as claimed in claim 1, the coated face being the external face.

18. A solar module comprising at least one photovoltaic cell of the Si, CIS, CdTe, a-Si, GaAs or GaInP type, wherein it uses as the outer substrate the coated substrate as claimed in claim 1, the coated face being the external face.

19. The solar module as claimed in claim 18, wherein its efficiency, expressed as an integrated current density of at least 2.5% up to 3.5%, is greater than that of a module using an outer substrate not containing the antireflection porous coating.

20. A solar module comprising:
said coated substrate as claimed in claim 1, which is flat and made of tinted glass; and
at least one solar cell of the Si, CIS, CdTe, a-Si, GaAs or GaInP type, which is joined to a second flat substrate made of glass, and is laminated to the coated substrate using a lamination interlayer, the porous coating being on the lamination face.

21. A multiple glazing unit comprising:
a substrate chosen to be flat and made of glass coated as claimed in claim 1; and
a second flat substrate, made of glass, which is laminated to the coated substrate using a lamination interlayer, the porous coating being on the lamination face.

22. A luminous laminated structure comprising:
a transparent first flat substrate, of given optical index n₁, made of a clear or extra-clear glass;
a bulk-tinted second flat substrate;
a lamination interlayer between the first and second substrates;
a porous coating forming an optical separator, deposited on the lamination interlayer or on the first substrate, the coating having an optical index n₂, and the difference n₂−n₁ being equal to or greater than 0.1;
a light source coupled into the edge of the first substrate, and
an internal backscattering network between the porous coating and the first substrate and/or an external scattering network on the external face of the first substrate.

23. The luminous laminated structure as claimed in claim 22, wherein the coated interlayer or the first coated substrate is the coated substrate as claimed in claim 1.

24. A process for manufacturing a porous coating of the sol-gel type on a glass substrate, wherein said process comprises
maturing a precursor sol which is a precursor of the constituent material of the coating, and comprises doped or undoped silicon oxide, in a solvent;
mixing the sol with a solid pore-forming agent in the form of polymeric particles and/or in the form of nanodroplets in a first liquid, said agent being dispersed in an immiscible, water-based second liquid, the particles and/or the nanodroplets being at least 20 nm in size;
depositing the mixture on the substrate;
condensing the precursor sol around the pore-forming agent; and
heat, treating the substrate at least 500° C. for a time not exceeding 15 minutes.

25. A process for manufacturing a porous coating of the sol-gel type on a plastic and/or glass substrate, wherein said process comprises:
maturing a precursor sol, which is a precursor of the constituent material of the coating, and comprises doped or undoped silicon oxide, in a solvent, the sol being chosen from a potassium, sodium or lithium silicate, or a sol of the hybrid silica type;
mixing the sol with a solid pore-forming agent in the form of polymeric particles, or in the form of nanodroplets in a first liquid, said agent being dispersed in an immiscible, water-based second liquid, the particles and/or the nanodroplets preferably being at least 20 nm in size;
depositing the mixture on the substrate;
condensing of the precursor sol around the pore-forming agent; and
removing the pore-forming agent from the coating by a polymer-extracting solvent, followed by densification by drying at 80° C. using infrared with blown air or UV treatment.
